(19) United States
(12) Patent Application Publication
(10) Pub. No.: US 2011/0170657 A1
(43) Pub. Date: Jul. 14, 2011

(54) ANALOG COUNTER AND IMAGING DEVICE INCORPORATING SUCH A COUNTER

(76) Inventors: Christophe Mandier, LaTour-Du-Pin (FR); Gilles Chammings, Grenoble (FR); Bertrand Dupont, Gargas (FR); Michaël Tchagaspanian, Ismier (FR)

(21) Appl. No.: 13/119,479

(22) PCT Filed: Sep. 15, 2009
(86) PCT No.: PCT/FR2009/051728

§ 371 Date: Mar. 17, 2011

(30) Foreign Application Priority Data
Sep. 18, 2008 (FR) 0856301

(51) Int. Cl. H03K 25/00

(52) U.S. Cl. 377/94

(57) ABSTRACT

An analog counter includes, for at least one step, an input for receiving electric pulses and a means for modifying, by consecutive increments or decrements, a storage voltage for each received electrical pulse, a means for resetting the storage voltage, and a comparator for comparing the storage voltage with a threshold voltage and adapted to generate exceedance information. The counter further includes a control means adapted to control the resetting means in the event of the simultaneous detection of exceedance information from the comparator and of an input pulse.

### PRIORITY CLAIM

This application is a Section 371 nationalization of PCT Application No. PCT/FR2009/0151728, filed Sep. 15, 2009, which claims priority to French Patent Application No. 0856301, filed Sep. 18, 2008, the disclosure of which is incorporated herein.

### TECHNICAL FIELD

The invention concerns an analog counter and an imaging device, in particular an infrared imaging device, incorporating such an analog counter.

### BACKGROUND

Imaging devices, in particular in the infrared range, are conventionally formed from a high number of pixels each adapted to measure the quantity of radiation it receives (each pixel in general being associated with a particular direction of the radiation received by means of an optical system).

The physical quantity measured at each pixel (by means of a sensor provided for that purpose) must be converted into a signal that can easily be exploited, for example of digital type.

In this context it has been provided for part of the conversion processing to be integrated into each pixel of the imaging device in particular so as to transmit only sufficiently robust signals out of the pixel.

It is furthermore known that reducing the dimensions of the pixels as much as possible is aimed at, which in particular involves reducing the dimensions of the processing circuits provided as explained above in each pixel.

The paper “A Multi-Spectral Analog Photon Counting Read-Out circuit for X-ray Hybrid Pixel Detectors” by M. Prenzoni et al. in Instrumentation and Measurements Technology Conference, Sorrento, Italy, 24-27 Apr. 2006 [IMTC 2006], IEEE, pp. 2003-2006 has in this context proposed to use analog counters instead of binary counters in order to reduce the surface area required.

The implementation proposed in that document is however rudimentary and it is desirable to improve in particular the repeatability and the accuracy of the counter in order to obtain an imaging device of good quality.

### SUMMARY

The invention thus provides an analog counter comprising, for at least one stage, an input adapted to receive electrical pulses, means for modifying, by successive increments or decrements, a storage voltage at each pulse received and means for resetting the storage voltage, comprising a comparator for comparing the storage voltage with a threshold adapted to generate exceedance information and control means adapted to control the resetting means in case of simultaneous detection of the exceedance information from the comparator and of an input pulse.

The resetting (the implementation of which may possibly be used as an input signal for the following stage) is thus made in synchronism with a pulse received as input, which provides accurate operation of the counter.

The comparator may comprise means for maintaining the exceedance information in the absence of resetting (in particular while awaiting the next pulse), that is to say until later resetting, which makes it possible to ensure that the resetting will indeed take place despite the condition mentioned earlier.

It may also be provided for the comparator to be capable of generating the exceedance information subsequently to the presence of the input pulse that caused the storage voltage to pass the threshold, which enables the resetting to be triggered precisely on the pulse following that which led to the exceedance of the threshold and thus to fully use the voltage range provided for the storage voltage.

It is thus possible to make provision for enabling the simultaneous detection of the exceedance information and of the input pulse uniquely on reception of a pulse subsequent to an input pulse that led to the generation of the exceedance information.

In practice the comparator has for example a response time greater than the duration of the pulses and less than the period separating two pulses, which enables the exceedance information to appear after the input pulse that led the storage voltage to go beyond the threshold but before the following impulse, which will thus lead to the resetting.

The analog counter may further comprise means for forcing the storage voltage to a predetermined voltage greater than the threshold, that are controlled by a forced resetting signal. Means for forced resetting of the stage are thus produced in a particularly clever way.

The control means may be adapted to transmit a pulse to the input of a following stage which pulse depends on the presence of the exceedance information and said input pulse. The two stages concerned thus work synchronously and the counting is thus particularly accurate. The pulse transmitted to the following stage may in practice be applied as a control signal for said resetting means, which simplifies the design of the apparatus.

The means for modifying the storage voltage comprise for example in practice a charge injection circuit, which may possibly itself comprise three PMOS transistors in series, of which two are end transistors which receive on the gate respectively a signal carrying the pulses and a signal that is complementary to said carrying signal.

As for the comparator, this may comprise two transistors forming a differential pair and respectively receiving on their gate the storage voltage and the threshold, as well as a transistor controlled by the exceedance information and connected in parallel to the transistor receiving the threshold so as to short-circuit it in the presence of the exceedance information. A hysteresis function is thus obtained in a particularly simple way as explained in more detail below.

It may furthermore be provided for the control means to comprise an inverter receiving as input the exceedance information and of which a bias terminal is connected to said input, which enables the detection of the aforementioned condition to be made particularly simply. Another inverter may furthermore put into form the exceedance information received from the comparator, in particular when the comparator generates a voltage ramp as output on account of its response time referred to previously.

According to one possibility for implementation described later, the analog counter comprises at least one capacitance (for example two capacitances) storing the storage voltage at least temporarily and connected to the means for modifying the storage voltage via a transistor, so as to be able to selectively disconnect the capacitance from those means in particular with the object of reading the stored value.

A differential pair may furthermore receive the storage voltage, while being selectively supplied according to a read signal, so as to transmit the stored value out of the pixel through the differential pair at the command of the read signal.

The invention also provides an imaging device comprising measuring means generating an electrical carrying signal of pulses the frequency of which represents a received radiation, and an analog counter as described above, the electrical signal being applied to said input.

### BRIEF DESCRIPTION OF THE DRAWING

Other features and advantages of the invention will appear more clearly in the light of the following description, made with reference to the accompanying drawings in which:

FIG. 1 represents the main elements of a pixel of an imaging device incorporating an analog counter in accordance with the teachings of the present invention;

FIG. 2 diagrammatically represents the functional elements of an example of an analog counter produced in accordance with the teachings of the invention.

FIG. 3 represents a detailed example of a possible embodiment for a stage of the analog counter of FIG. 2;

FIG. 4 represents the design of the bus enabling the connection of the stage represented in FIG. 3 to the other elements of the pixel column concerned;

FIG. 5 illustrates the temporal behavior of certain signals present in the circuit of FIG. 3.

### DETAILED DESCRIPTION

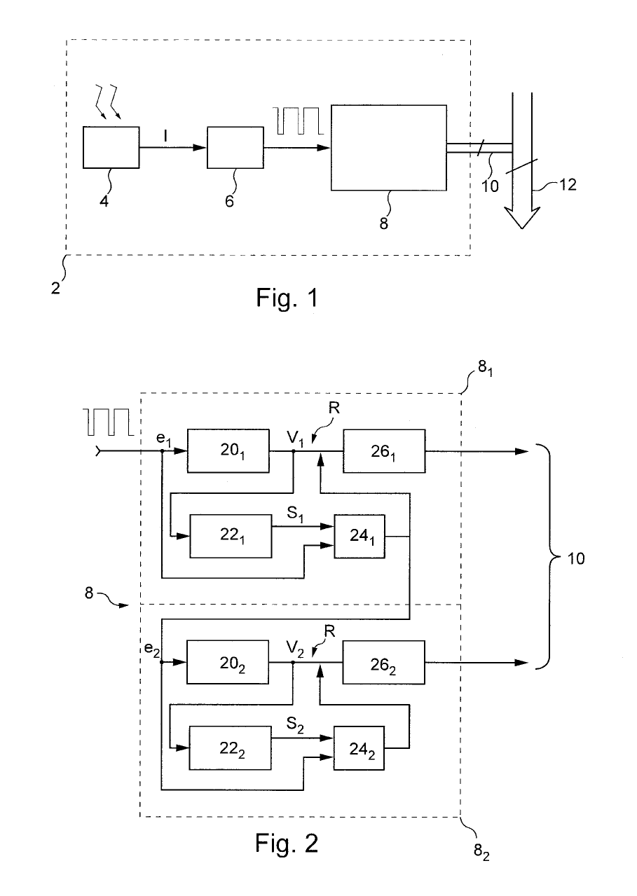

FIG. 1 represents the general diagram of an infrared imaging device pixel 2 comprising a counter produced according to the teachings of the invention. An infrared imaging device is naturally composed of a matrix of a high number of such pixels 2.

Each pixel 2 comprises a sensor 4 (comprising for example a micro-bolometer and a biasing transistor) adapted to generate a current I that is indicative (in particular is variable depending on) the flux of infrared radiation received in a given passband.

The current I so generated is applied to a current-frequency conversion circuit which outputs electrical pulses at a frequency dependent on the current I.

It may be noted that the electrical pulses may be constituted by a high logic level or as a variant by a low logic level (as is moreover represented in FIG. 1 and in the examples described below).

The electrical pulses emitted by the conversion circuit 6 are applied to an analog counter 8, described in detail below, the main role of which is to count the number of pulses received over a predetermined time (the counter 8 being reset with a period equal to that time) with the aim of outputting signals onto a bus 10 that represent the counted number, and which consequently represent the infrared radiation flux received by the sensor 4.

As will become clear in particular from the following explanations, the counter 8 generates a voltage, on each conductive element of the bus 10, at a predetermined number N of levels (and which consequently represent on each conductor element an integer between 0 and N−1), such that the whole of the bus will represent the number of pulses counted in base N, hence the designation base N counter (where N is preferably strictly greater than 2 in order to obtain the advantages in terms of reduction in area already referred to).

The voltage levels borne by the bus 10 may then be transmitted onto a main bus 12 onto which the values measured for the different pixels of a column are transmitted successively (in particular by time-division multiplexing) for them to be converted into digital then for them to be stored in memory.

Variants may naturally be provided, such as for example the analog to digital conversion of the signals present on the bus 10 before their transmission to the foot of the column by means of the main bus 12. Mechanisms for temporary storage of the voltage levels by means of capacitances may also be provided.

FIG. 2 is a general block diagram representation of an example embodiment of the counter 8.

The counter 8 represented in FIG. 2 comprises a first stage 81 and a second stage 82. A higher number of stages may naturally be provided, each stage being sequentially linked to the following stage in the same way as the first stage 81 is sequentially linked to the second stage 82 as described later.

All the stages (here the first stage 81 and the second stage 82) are formed on the basis of the same architecture and the architecture of a stage 8i will now be described.

Each stage 8i receives as input an electrical pulse train eᵢ which is then applied to a charge injection circuit 20ᵢ and applied to a resetting circuit 24i (the subject of which will be returned to later).

The charge injection circuit 20ᵢ is designed to increase its output voltage Vᵢ by a set value (or voltage increment) ΔV at each pulse of the signal eᵢ (which pulse corresponds to a low level in the example described here as already mentioned). This increase in the voltage level by a set increment is obtained in practice by the injection, by the circuit 20ᵢ, of a set quantity of charges, kept at the point denoted R (which carries the voltage Vᵢ) on account of the presence of a capacitance in the memory storage circuit 26i as described in more detail below.

Circuits of this type are for example described in the French patent application no. FR 2 888 074.

For example 8 analog levels (N=8) are used for a voltage range of the order of 1.4 V, here between a lowest analog level of 0 V (ground potential GND) and a highest analog level of approximately 1.4 V (the supply voltage being 1.8 V). Different values could naturally be provided; the lowest analog level could for example be non-zero.

The voltage Vᵢ is applied in particular to the input of a comparator 22ᵢ which generates an exceedance signal Sᵢ when the voltage V1 has attained its highest analog level (which is determined for example by comparison to a threshold slightly lower than that analog level).

The comparator 22ᵢ comprises a hysteresis mechanism such that, once the voltage Vi has exceeded the threshold, the exceedance information Si is kept for so long as the voltage V1 has not returned to its lowest analog level as now explained.

The comparator 22ᵢ moreover has a response time greater than the duration of the pulses eᵢ (but less than the time separating two pulses) such that the exceedance information Sᵢ is generated after the pulse that caused its appearance, as illustrated in FIG. 5. In practice, as the pulses have a duration of the order of a few nanoseconds (less than 10 ns) and are separated from each other by a minimum of 300 ns, a response time of the order of 100 ns can be provided.

The exceedance information Sᵢ is applied to the resetting circuit 24ᵢ which also receives the pulse carrying signal eᵢ received as input.

The resetting circuit 24ᵢ commands the return of the voltage Vᵢ to the lowest analog level when it receives as input both the exceedance information Sᵢ and a pulse of the input signal eᵢ. As will be seen below, the resetting is for example carried out by discharge of the capacitance for memory storage of the voltage Vᵢ already referred to above. It will then be noted that the time necessary for cancelling the exceedance information after reception of a pulse is preferably greater than the length of that pulse and less than the minimum time between two consecutive pulses.

As already indicated, the memory storage circuit 26ᵢ enables the temporary storage (in particular during the counting) of the voltage Vᵢ by means of a capacitance, then, when the counting time has elapsed, enables the transmission of the voltage Vᵢ obtained at the end of counting (which thus represents the number of pulses received at the input eᵢ modulo N) on the bus 10.

The signal sent as output from the resetting circuit 24ᵢ is furthermore transmitted as input signal eᵢ₊₁ for the following stage (unless of course it is the last stage), as shown in FIG. 2 wherein the output from the resetting circuit 24₁ is applied as input signal e₂ for the second stage 8₂, and thus in practice to the injection circuit 20₂ and to the resetting circuit 24₂ of the second stage 8₂.

Each stage (as from the second stage) thus counts one pulse when the preceding stage, after having scanned the N analog levels, is reset (which constitutes the basic principle of the base N counting).

It may be noted that, because the resetting circuit 24ᵢ outputs its signal only in the presence of a pulse in the signal eᵢ that it receives as input, the pulses of that signal output from the resetting circuit 24ᵢ are synchronous with the pulses of the signal eᵢ with regard to phase (that is to say the point in time of the start of the pulses). Furthermore, where the cancelling of the exceedance information is sufficiently slow relative to the pulse of the signal eᵢ that generated it, the pulses of the output signal from the resetting circuit 24ᵢ are substantially of the same length as the pulses of the channel eᵢ.

The use of this output signal as input to the following stage, thus, for one thing, makes it possible to match the pulses received at the stage eᵢ₊₁ with those of the signal eᵢ received as input from the preceding stage, and thus obtain synchronous operation of the different stages.

Furthermore, as the length of the input pulses is the same for the stage concerned (signal eᵢ) and for the following stage (signal eᵢ₊₁), the quantity of charges injected by the various injection circuits 20ᵢ, which naturally depends on the length of the pulses received as input, is particularly uniform over all the stages, which makes it possible to obtain voltage increments that are identical in the different stages.

Moreover, in particular thanks to the reaction time of the comparator, the architecture presented above enables the resetting to zero to be triggered precisely on arrival of the pulse following that which led to the exceedance of the threshold (that is to say the arrival of the last analog voltage level) which also leads to a very precise operation of the counter (whereas on the contrary resetting just on the basis of the exceedance information provided in the conventional systems would be premature and would lead to the loss of the last analog level).

This property thus makes it possible to fully use the voltage range. Compared with the conventional systems, it is possible either to obtain an additional analog level for the same voltage increment (with an identical noise sensitivity), or to obtain a higher voltage increment for an identical number of levels and thus to have a better signal-to-noise ratio.

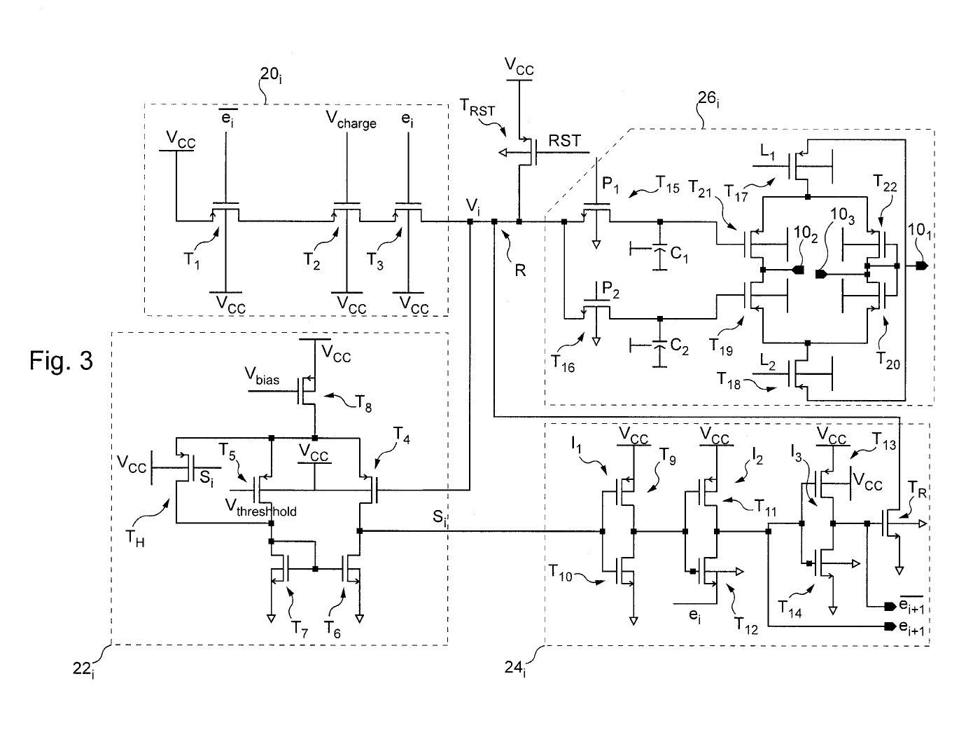

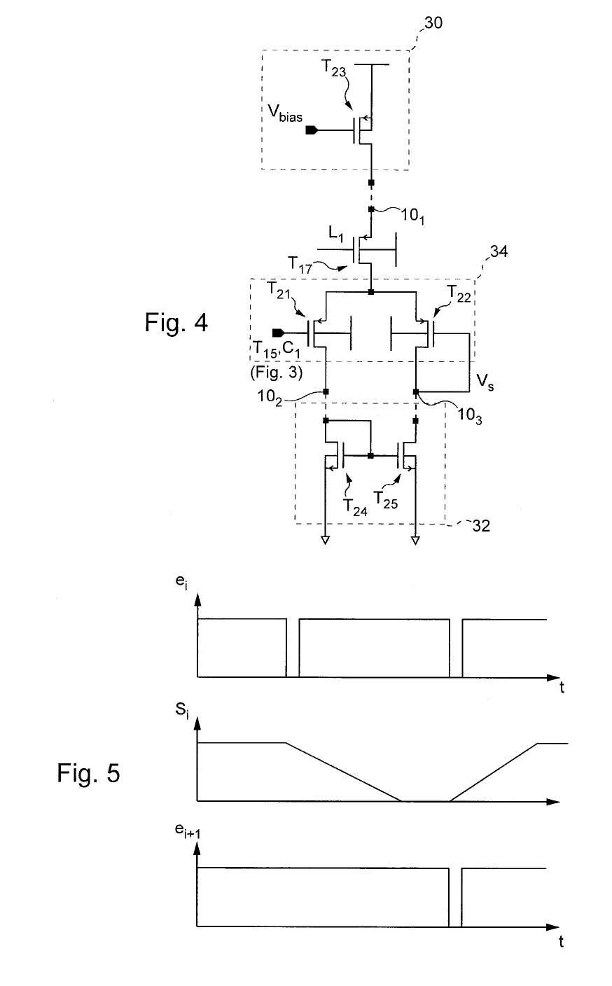

FIG. 3 represents a detailed example of implementation that may be provided for each stage 8₁, 8₂ of the counter of FIG. 2.

It may be noted at the outset that, in this detailed implementation, not only are the pulse carrying signals eᵢ used as input for each stage, but also the complementary signal e̅ᵢ̅.

It may moreover be noted that, in FIG. 3, the supply of certain circuits with the nominal supply voltage of the electronic circuit is denoted V_{cc} (here V_{cc}=1.8 V), whereas the connection to a triangle represents a connection to ground.

The charge injection circuit 20ᵢ comprises three PMOS transistors T₁, T₂, T₃ connected in series (that is to say that the drain of one is connected to the source of the other), the source of the first T₁ of these three PMOS transistors being connected to the voltage V_{cc} whereas the drain of the third PMOS transistor T₃ forms the output from the injection circuit 20ᵢ, where the voltage Vᵢ is established that represents the number of counted pulses.

The first transistor T₁ receives on its gate the signal e̅ᵢ̅ that is complementary to the input signal eᵢ, the second transistor T₂ receives on its gate a fixed voltage V_{charge} and the third transistor T₃ receives on its gate the input signal eᵢ.

Thus, when a pulse arrives in the input signal eᵢ (a pulse being represented by a low level in that signal in the example described here as already mentioned above), the third PMOS transistor T₃ becomes conducting (whereas the first transistor T₁ is non-conducting on account of the complementary signal e̅ᵢ̅) such that the charges previously accumulated between the first and third transistors T₁, T₃ (before the arrival of the pulse) are transferred to the output of the injection circuit 20ᵢ and thus cause the increase in the voltage Vᵢ by a predetermined increment ΔV.

Once the pulse in the signal eᵢ has passed, the third transistor T₃ becomes non-conducting whereas the first transistor T₁ becomes conducting, which causes the accumulation of charges to transmit as output during the following pulse.

The set voltage V_{charge} is provided by a voltage source and is used by several stages, or even by several pixels. The level of this set voltage V_{charge} is constant during the acquisition operation but it may be provided for it to be variable, for example during a calibration phase, so as to adjust the quantity of charges transmitted on each pulse.

Moreover, PMOS transistors are preferably used in the injection circuit 20ᵢ as already stated on account of the low level generally observed of their leakage current relative to transistors produced using NMOS technology.

As already mentioned with regard to FIG. 2, the voltage Vᵢ output from the injection circuit 20ᵢ (point R) is applied as input to the comparator 22ᵢ, where it is compared with a set voltage V_{threshold} which is slightly lower (for example approximately 100 mV lower in the present example in which the analog levels differ by approximately 200 mV) than the highest analog level which the voltage Vᵢ may take. It may also be noted here that the voltage may possibly be adjustable during a calibration phase preceding normal operation, with the aim in particular of compensating for the possible technological dispersions (lack of uniformity in the values obtained in practice over all the pixels).

The comparator 22ᵢ comprises a PMOS transistor T₄ the gate of which receives the voltage Vᵢ and a PMOS transistor T₅ the gate of which receives the voltage V_{threshold}, the transistors T₄ and T₅ being connected by their respective sources to a point to which is also connected the drain of a PMOS transistor T₈ the source of which is set to the supply voltage V_{CC} and the gate of which receives a biasing voltage V_{bias}.

The drains of the transistors T₄ and T₅ are respectively connected to ground GND by an NMOS transistor T₆ and by an NMOS transistor T₇ (each having their source connected to ground), the transistors T₆ and T₇ being connected by their respective gates to a point that is also connected to the drain of the transistor T₇.

It is also provided to connect the source and the drain of the transistor T₅ with interposition of a PMOS transistor T_{H} (the sources of the transistors T₅ and T_{H} being in contact) so as to create a “hysteresis” branch, the transistor T_{H} also receiving on its gate the voltage Sᵢ present at the drain of the transistor T₄.

So long as the voltage Vᵢ is less than the voltage V_{threshold}, the voltage Sᵢ (present in particular at the drain of the transistor T₄ as has just been stated) is at the high level (in the example described here representing an absence of exceedance information).

The transistor T_{H}, to which is also applied the voltage Sᵢ and which enables the hysteresis function to be generated as described below, is then deactivated,

When the voltage Vᵢ increases due to the counting of the pulses as described above until the voltage V_{threshold} is exceeded, the voltage Sᵢ passes to zero (so indicating the exceedance of the threshold at the resetting circuit 24ᵢ with the consequences detailed below), with the reaction time already mentioned (see for example FIG. 5), the effect of which is furthermore to command the closing of the transistor T_{H} and to activate the “hysteresis” branch which includes that transistor T_{H} and which thereby short-circuits the transistor T₅ of the comparator which receives the voltage V_{threshold}.

Due to this, the comparator will continue to deliver the exceedance information (Sᵢ at zero) so long as the voltage Vᵢ itself has not returned to zero due to the resetting to come as now explained.

As already stated, the exceedance information borne by the voltage Sᵢ is applied as input to the resetting circuit 24ᵢ.

The resetting circuit 24ᵢ successively comprises three inverters I₁, I₂, I₃.

The first inverter I₁ comprises a PMOS transistor T₉ and an NMOS transistor T₁₀ which are linked by their respective drains (at a point which constitutes the output from the first inverter I₁) and which each receive the voltage Sᵢ on their gate, the sources of the transistors T₉ and T₁₀ being respectively linked to the supply voltage V_{CC} and to the ground GND.

The second inverter I₂ comprises a PMOS transistor T₁₁ and an NMOS transistor T₁₂ which are linked by their respective drains (at a point which constitutes the output of the second inverter I₂) and which each receive the output from the first inverter I₁ on their gate, the source of the transistor T₁₁ being linked to the supply voltage V_{CC} while the signal eᵢ received as input from the stage concerned is applied to the source of the transistor T₁₂.

The signal output from the second inverter I₂ is transmitted to the following stage as input signal eᵢ₊₁ as explained below.

The third inverter I₃ comprises a PMOS transistor T₁₃ and an NMOS transistor T₁₄ which are linked by their respective drains (at a point which constitutes the output of the third inverter I₃) and which each receive the output from the second inverter I₂ on their gate, the sources of the transistors T₁₃ and T₁₄ being respectively linked to the supply voltage V_{CC} and to the ground GND.

The signal output from the third inverter I₃ is in particular transmitted to the following stage as signal e̅ᵢ̅₊̅₁̅ which is complementary to the input signal eᵢ₊₁.

An explanation is now given of the operation of these three inverters in series.

As already indicated, the voltage Sᵢ is applied to the input of the first inverter I₁ which thus generates a signal as output in which the exceedance information generated by the comparator 22ᵢ corresponds to a high level.

It is may be noted that the first inverter I₁ puts in form the signal Sᵢ (which has the form of a voltage ramp on account of the reaction time of the comparator which is greater than the length of the pulses as already mentioned) and that it may therefore be considered that the exceedance information is generated when the signal Sᵢ is sufficiently weak to lead to the switching of the first inverter I₁, here to a high output state.

As for the second inverter I₂ this receives (at the source of the NMOS transistor T₁₂ as already indicated) the pulse carrying signal eᵢ received as input from the stage 8ᵢ concerned such that the output from the second inverter I₂ is at a low level if and only if there are simultaneously present a pulse (low level) in the signal eᵢ and the exceedance information received from the comparator 22ᵢ. The output from the second inverter I₂ may thus be used as input signal eᵢ₊₁ for the following stage, with pulses that are substantially synchronous with those of the signal eᵢ (the temporal offset generated by the second inverter I₂ being negligible in the present application).

This signal is also applied to the third inverter I₃ which makes it possible to generate both the complementary signal e̅ᵢ̅₊̅₁̅ destined for the following stage and the command for an NMOS resetting transistor T_{R} which, when it becomes conducting (that is to say when the output signal from the third inverter I₃ is at the high level) discharges the voltage Vᵢ accumulated at the output from the injector circuit 20ᵢ, which causes the resetting to zero (or reinitializing) of the counter stage.

It may be noted that very good synchronism is thereby obtained between the resetting to zero (or reinitializing) of a stage 8ᵢ and the counting of a pulse at the stage 8ᵢ₊₁, which are features of base N counting.

According to a variant which may be provided, the two inverters and I₂ could be replaced by a flip-flop type latch and the same functionalities be obtained: in this case the latch receives as input the signal Sᵢ and the signal eᵢ on its clock input, which enables a signal eᵢ₊₁ to be obtained as output in accordance with what is described above.

The resetting, which has just been described as a consequence of reaching the highest analog level by the output voltage Vᵢ, may also be commanded by application of a pulse of a signal RST to the gate of a PMOS transistor T_{RST} the drain of which is linked to the point R (carrier of the voltage Vᵢ) and the source of which is connected to the supply voltage V_{cc}: as the transistor T_{RST} becomes conducting, the nominal voltage (supply voltage) V_{cc} is applied to the point R; the voltage Vᵢ is then equal to the supply voltage V_{cc} and consequently is greater than the highest analog value (and thus greater than the voltage V_{threshold}), which triggers the operation already described within the comparator 22ᵢ and the resetting circuit 24ᵢ and subsequently the resetting of the voltage Vᵢ.

It should be noted that the resetting of the counter is carried out in practice on arrival of a pulse as input from the comparator. This type of resetting is preferable to resetting by means of a discharging NMOS transistor. This is because, on opening of such an NMOS transistor after discharging, a negative voltage may appear at point R. This accentuates the leakages of the transistors linked to that node and it is then difficult to ensure a fixed and determined analog low level. This uncertainty as to the level of the point R may furthermore be accentuated if the waiting time between the resetting and the actual counting is not limited. Thus, by resetting the counter as indicated above, at a time when it is desired to count input pulses, it is possible to control the voltage present on the node R after resetting. Furthermore, the fact of providing resetting of the node R to a voltage equal to or greater than the ground, enables reduction of the parasitic leakages to the node R of each stage. The low analog level is thus substantially the same for each stage independently of the time at which counting starts for each stage.

A forced resetting mechanism for the stage is thus obtained very simply, which furthermore uses the same components and the same process as the resetting for the stage each time the threshold is exceeded during counting, which in all cases enables identical resetting of the voltage Vᵢ (and which is thus well calibrated); this mechanism is in particular used for resetting the counter to zero (forced resetting of all the stages of the counter) when the duration of counting has elapsed (and naturally after storage of the value as now described).

The memory circuit 26ᵢ comprises two capacitances C₁, C₂, each being connected to the output of the injection circuit 20ᵢ (point R of voltage Vᵢ) by an NMOS transistor (respectively denoted T₁₅, T₁₆) respectively controlled by signals P₁, P₂.

The applied signals P₁, P₂ are such that by operation only one of the two capacitances C₁, C₂ is connected to the output of the injection circuit 20ᵢ, the capacitance that is connected (for example C₁) enabling the temporary memorization (or storage) of the value for the duration of the counting.

When that duration has elapsed, the previously closed transistor opens (naturally on account of its appropriate control, in the example by the signal P₁) which makes it possible to isolate the capacitance concerned (Cᵢ in the example) and to keep the value representing the number of counted pulses.

It is then possible to close the transistor enabling the connection of the other capacitance (C₂ in the example) to the output of the injection circuit 20ᵢ and to command the forced resetting of the stage (which incidentally is simultaneous with that of the other stages of the counter) by command using the signal RST as mentioned earlier.

The counting of the pulses received thus resumes with the temporary storage on that other transistor (C₂ in the example). This new counting period is taken advantage of to transmit the value stored on the first capacitance (C₁ in the example) to the bus 10 as described below (reading of the value stored on the capacitance to the bus 10 using follower circuits controlled by the read signals L₁, L₂).

More particularly, each capacitance C₁, C₂ is connected to the bus 10 via a differential pair supplied through a PMOS transistor (respectively denoted T₁₇, T₁₈) receiving on its gate the read signal (respectively L₁, L₂).

More precisely, the terminal of the capacitance C₁ linked to the transistor T₁₅ is also connected to the gate of a PMOS transistor T₂₁ the source of which is connected to the source of a PMOS transistor T₂₂ (to form the differential pair) and also connected to the drain of the transistor T₁₇. The gate of the transistor T₂₂ is moreover connected to the drain of that same transistor T₂₂.

The bus 10 is here formed from three wires 10₁, 10₂, 10₃ respectively connected to the source of the transistor T₁₇ (for connection to a source of current at the column head as explained later), to the drain of the transistor T₂₁ and to the drain of the transistor T₂₂ (for connection to a current mirror at the column foot as explained later).

In identical manner, the terminal of the capacitance C₂ linked to the transistor T₁₆ is also connected to the gate of a PMOS transistor T₁₉ the source of which is connected to the source of a PMOS transistor T₂₀ (to form the differential pair) and also connected to the drain of the transistor T₁₈. The gate of the transistor T₂₀ is moreover connected to the drain of that same transistor T₂₀.

The three wires 10₁, 10₂, 10₃ of the bus 10 are thus respectively connected to the source of the transistor T₁₈ (for connection to the source of current at the column head), to the drain of the transistor T₁₉ and to the drain of the transistor T₂₀ (for connection to the current mirror at the column foot).

FIG. 4 represents the differential pair 30 (transistors T₂₁, T₂₂) and the transistor T₁₇ (associated with the capacitance C₁ as described earlier) and their connection to the components at the column head and at the column foot as briefly mentioned earlier. In the interest of simplification, the components (T₁₈, T₁₉, T₂₀) associated with the capacitance C₂ are not represented in FIG. 4; their connection at the column head and foot is however made in identical manner as already explained with reference to FIG. 3.

As clearly visible in FIG. 4, the source of the transistor T₁₇ receiving the read signal L₁ is connected via the wire 10₁ of the bus 10 to the drain of a PMOS transistor T₂₃ situated at the column head 30 and forming a current source (on account of the fact that its source is placed at the supply voltage V_{cc}).

As for the drains of the transistors T₂₁, T₂₂ forming the differential pair 34, these are respectively connected by the wires 10₂, 10₃ of the bus 10 to the drains of NMOS transistors T₂₄, T₂₅ situated at the column foot 32 and forming a current mirror, the drain of the transistor T₂₄ also being connected to the gates of the transistors T₂₄ and T₂₅ and the sources of these transistors T₂₄, T₂₅ being connected to the ground GND.

The components (T₂₃, T₂₄, T₂₅) at the column head 30 and at the column foot 32 are common to all the pixels of the column; thus, for each of the pixels of the column, the bus 10 is connected to these components T₂₃, T₂₄, T₂₅ in identical manner to that just described for the pixel represented in FIG. 4.

It can thus clearly be seen that the closing of the transistor T₁₇ relative to a particular pixel (closing controlled by the read signal L₁) makes it possible to connect (between the current source and the current mirror) the differential pair 34 of the pixel concerned and to thereby read, on the gate of the transistor T₂₂, a value Vₛ corresponding to that stored by virtue of the capacitance C₁ in the pixel concerned.

In the same way the value stored by the capacitance C₂ is read by closing the associated transistor T₁₈ by means of the signal L₂.

The read value may then be processed, for example converted into digital as already indicated.

Naturally, the foregoing embodiment is merely a possible example of implementation of the invention, which is not limited thereto.

Circuits other than those presented above could in particular be used to perform the functions of charge injection, comparison and resetting.

It could also be provided to count the pulses by resetting the stored voltage to a maximum value and by decrementing that value at each received pulse.

Moreover, an example of a circuit produced using CMOS technology has been described, but implementations in other technologies could naturally be envisaged, such bipolar logic, or with transistors that are complementary to those which have been described (in which case provision could for example be made for the input pulse to be applied to the head of the corresponding inverter at I₂)

Where the technology for producing the circuit makes it possible to have “thin gate” transistors operating for example with a maximum voltage of 1.8V and “thick gate” transistors operating for example with a voltage of 3.3V it would moreover be possible to use thick gate transistors which generally have lower leakage. Such transistors could advantageously be used to produce the charge injection circuit, the resetting transistors T_{R} and T_{RST} and the first inverter I₁.

1. An analog counter comprising, for at least one stage:
an input adapted to receive electrical pulses;
means for modifying, by successive increments or decrements, a storage voltage at each pulse received;
means for resetting the storage voltage;
a comparator for comparing the storage voltage with a threshold voltage and adapted to generate exceedance information; and
control means adapted to control the means for resetting in case of simultaneous detection of the exceedance information from the comparator and of an input pulse.

2. An analog counter according to claim 1, wherein the comparator comprises means for maintaining the exceedance information until later resetting.

3. An analog counter according to claim 1 or 2 further comprising means for enabling the simultaneous detection of the exceedance information and of the input pulse uniquely on reception of a pulse subsequent to an input pulse that led to the generation of the exceedance information.

4. An analog counter according to claim 1, wherein the comparator has a response time greater than the duration of the input pulses and less than a period separating two input pulses.

5. An analog counter according to claim 1 further comprising means for forcing the storage voltage to a predetermined voltage greater than or less than the threshold voltage, that are controlled by a forced resetting signal.

6. An analog counter according to claim 1, wherein the control means are adapted to transmit a pulse to an input of a following stage wherein the pulse depends on the presence of the exceedance information and the input pulse.

7. An analog counter according to claim 1, wherein the means for modifying the storage voltage comprise a charge injection circuit.

8. An analog counter according to claim 7, wherein the charge injection circuit comprises three PMOS transistors in series, wherein two of the PMOS transistor are end transistors that receive on a gate respectively a carrying signal of the input pulses and a signal that is complementary to the carrying signal of the input pulses.

9. An analog counter according to claim 1, wherein the comparator comprises two transistors forming a differential pair and respectively receiving on their gate the storage voltage and the threshold voltage, and in which a transistor controlled by the exceedance information is connected in parallel to one of the two transistors that receives the threshold voltage so as to short-circuit it in the presence of the exceedance information.

10. An analog counter according to claim 1, wherein the control means comprise an inverter receiving as input the exceedance information and of which a bias terminal is connected to the input).

11. An analog counter according to claim 10 further comprising another inverter adapted to put into form the exceedance information received from the comparator.

12. An imaging device comprising several pixels, each pixel comprising measuring means generating an electrical carrying signal of pulses the frequency of which represents a radiation received by that pixel, and an analog counter according to claim 1, wherein the electrical signal is applied to the input of the counter.
